(19) United States
(12) Patent Application Publication
(10) Pub. No.: US 2008/0003837 A1
(43) Pub. Date: Jan. 3, 2008

(54) Substrate processing method and semiconductor device manufacturing method carried out in a lithographic process

(76) Inventors: Kei Hayasaki, Kamakura-shi (JP); Eishi Shiobara, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/812,015

(22) Filed: Jun. 14, 2007

(30) Foreign Application Priority Data
Jun. 16, 2006 (JP) 2006-167786

(51) Int. Cl. H01L 21/469; G03C 5/00

(52) U.S. Cl. 438/758; 430/315; 438/799; 257/E21.487

(57) ABSTRACT

In a substrate processing method, a substrate to be processed coated with a film containing a solvent is heated in a single wafer processing manner. The substrate to be processed is heated for a predetermined time by arranging the substrate to be processed in the proximity of a heated heating plate while passing a gas along a top surface of the substrate to be processed at a predetermined flow rate. The substrate to be processed is cooled to a temperature lower than a sublimation temperature of a substance contained in the film containing the solvent while passing a gas heated to a temperature equal to or higher than the sublimation temperature of the substance contained in the film containing the solvent along the top surface of the substrate to be processed.

### CROSS-REFERENCE TO RELATED APPLICATIONS

This application is based upon and claims the benefit of priority from prior Japanese Patent Application No. 2006-167786, filed Jun. 16, 2006, the entire contents of which are incorporated herein by reference.

### BACKGROUND OF THE INVENTION

1. Field of the Invention

The present invention relates to a substrate processing method and a semiconductor device manufacturing method carried out by means of a coating development processing apparatus used in a lithographic process in a semiconductor manufacturing method.

2. Description of the Related Art

In a lithographic process in the manufacture of a semiconductor integrated circuit, a substrate to be processed is subjected to a coating/baking process of an antireflection film and a coating/baking process of a resist film by a coating development processing apparatus. Then, a resist film formed on the substrate to be processed is subjected to a process of pattern-exposure performed via a mask by an exposure system. Further, the exposed resist film is subjected to a baking process and a development process in sequence by the coating development processing apparatus.

In the baking process performed after the antireflection film coating process and resist film coating process, the solvent of the applied liquid is mainly discharged into the heat treatment apparatus and is then removed from the heat treatment apparatus by exhaustion. However, in the case of the antireflection film which is baked at a high baking temperature, a sublimate is discharged into the heat treatment apparatus in addition to the solvent. The discharged sublimate adheres again to the substrate to be processed when exhaustion is insufficient, thereby causing a defect in some cases. Accordingly, in the prior art, such a problem is avoided by ensuring sufficient exhaustion.

However, with the micron-order reduction of the pattern size, the fatal defect size has become relatively small. Thus, even when exhaustion is sufficient, the sublimate discharged from the substrate to be processed immediately before termination of the heating process and is not collected becomes fine particles at the time of exchange of the substrate to be processed so as to adhere to the substrate to be processed, thereby causing a problem that the adhered particles give rise to a defect.

Incidentally, as a prior art associated with the present invention, Jpn. Pat. Appln. KOKAI Publication No. 2003-158054 discloses a substrate processing apparatus in which a gas introduced into a chamber is evenly blown against a surface of a substrate through an opening formed in a gas blow-out plate.

### BRIEF SUMMARY OF THE INVENTION

A substrate processing method according to a first aspect of the present invention is that of heating a substrate to be processed coated with a film containing a solvent in a single wafer processing manner, and comprises: heating the substrate to be processed for a predetermined time by arranging the substrate to be processed in the proximity of a heated heating plate while passing a gas along a top surface of the substrate to be processed at a predetermined flow rate; and cooling the substrate to be processed to a temperature lower than a sublimation temperature of a substance contained in the film containing the solvent while passing a gas heated to a temperature equal to or higher than the sublimation temperature of the substance contained in the film containing the solvent along the top surface of the substrate to be processed.

A substrate processing method according to a second aspect of the present invention is that of heating a substrate to be processed coated with a film containing a solvent in a single wafer processing manner, and comprises: heating the substrate to be processed for a predetermined time by arranging the substrate to be processed in the proximity of a heated heating plate while passing a gas along a top surface of the substrate to be processed at a predetermined flow rate; and cooling the substrate to be processed to a temperature lower than a solidification temperature of a substance contained in the film containing the solvent while passing a gas heated to a temperature equal to or higher than the solidification temperature of the substance contained in the film containing the solvent along the top surface of the substrate to be processed.

A semiconductor device manufacturing method according to a third aspect of the present invention, comprises: coating a semiconductor substrate with a film containing a solvent; baking the semiconductor substrate coated with the film containing the solvent; forming a resist film on the baked semiconductor substrate; baking the semiconductor substrate on which the resist film is formed; subjecting the baked resist film to pattern exposure; baking the resist film subjected to pattern exposure; and developing the exposed and baked resist film. The baking the semiconductor substrate includes heating the semiconductor substrate for a predetermined time by arranging the semiconductor substrate in the proximity of a heated heating plate while passing a gas along a top surface of the semiconductor substrate at a predetermined flow rate; and cooling the semiconductor substrate to a temperature lower than a sublimation temperature of a substance contained in the film containing the solvent while passing a gas heated to a temperature equal to or higher than the sublimation temperature of the substance contained in the film containing the solvent along the top surface of the semiconductor substrate.

### BRIEF DESCRIPTION OF THE SEVERAL VIEWS OF THE DRAWING

FIG. 1 is a flowchart showing a photolithographic process in the manufacture of a semiconductor integrated circuit.

FIG. 2 is a side cross-sectional view showing the structure of a heat treatment apparatus used in a substrate processing method of an embodiment of the present invention.

FIG. 3 is a flowchart showing the procedures of a general baking process.

FIG. 4 is a graph showing a relationship between heating time and an absorption amount of UV light in a general baking process.

FIG. 5 is a view showing a state in the chamber immediately before termination of a general baking process.

FIG. 6 is a view showing a state where the chamber is opened after termination of a general baking process and particles are produced.

FIG. 7 is a flowchart showing the procedures of a baking process of the embodiment of the present invention.

FIG. 8 is a graph showing a relationship between a heating temperature of a substrate to be processed and an absorption amount of UV light in the embodiment.

FIG. 9 is a view showing a state in the chamber after termination of the baking process of the embodiment.

### DETAILED DESCRIPTION OF THE INVENTION

An embodiment of the present invention will be described below with reference to the accompanying drawings. In the description, parts which are common throughout all the drawings are denoted by common reference symbols.

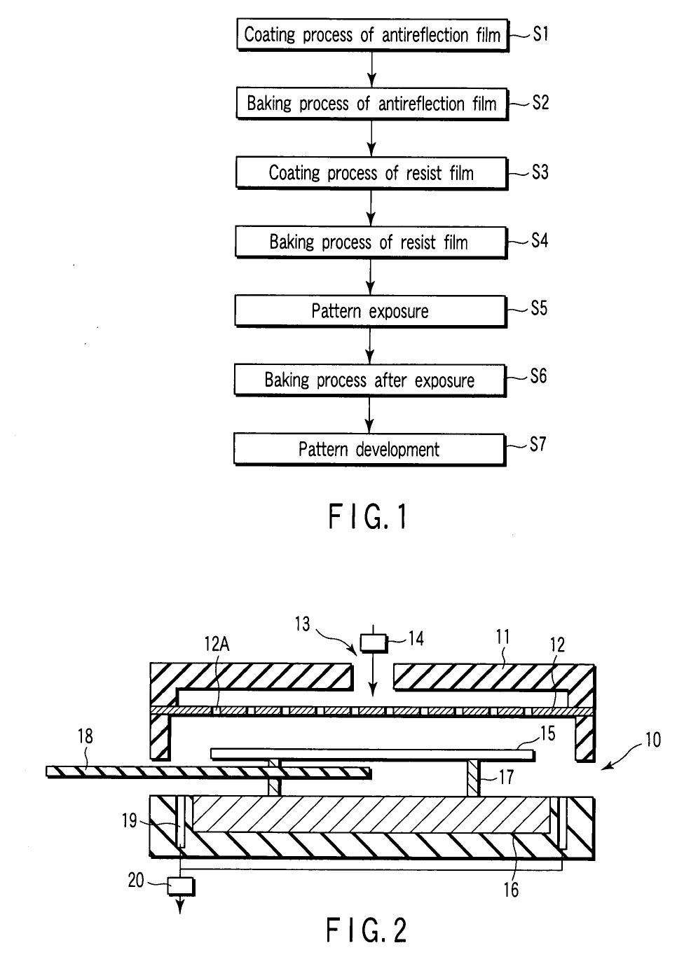

FIG. 1 is a flowchart showing a photolithographic process in the manufacture of a semiconductor integrated circuit.

In the photolithographic process in the manufacture of the semiconductor integrated circuit, a substrate to be processed is subjected to a coating/baking process of an antireflection film (steps S1 and S2), and a coating/baking process of a resist film by a coating development processing apparatus (steps S3 and S4). Subsequently, the resist film formed on the substrate to be processed is subjected to a process of pattern-exposure via a mask by an exposure system (step S5). Further, the exposed resist film is subjected to a baking process and a development process in sequence by a coating development processing apparatus (steps S6 and S7). In this embodiment, an example is shown in which an organic antireflection film formed on the substrate to be processed is subjected to a baking process.

FIG. 2 is a cross-sectional side view showing the structure of a heat treatment apparatus used for a substrate processing method of the embodiment of the present invention. A lid 11 is provided on the upper part of a chamber 10, and a top plate 12 is internally disposed in the upper portion of the chamber 10. An air inlet 13 is formed at the center of the lid 11, and air supply means 14 is connected to this air inlet 13. A plurality of holes 12A are formed, for example, radially. A heating plate 16 on which a wafer (semiconductor substrate) 15 is to be placed is provided in the lower portion of the chamber 10, and a plurality of support pins 17 are implanted in the heating plate 16 so that they can be raised/lowered. A transfer arm 18 for transferring the wafer 15 is arranged below the wafer 15. Furthermore, a plurality of exhaust ports 19 are formed in the lower end portion of the chamber 10, and exhausting means 20 is connected to the exhaust ports 19.

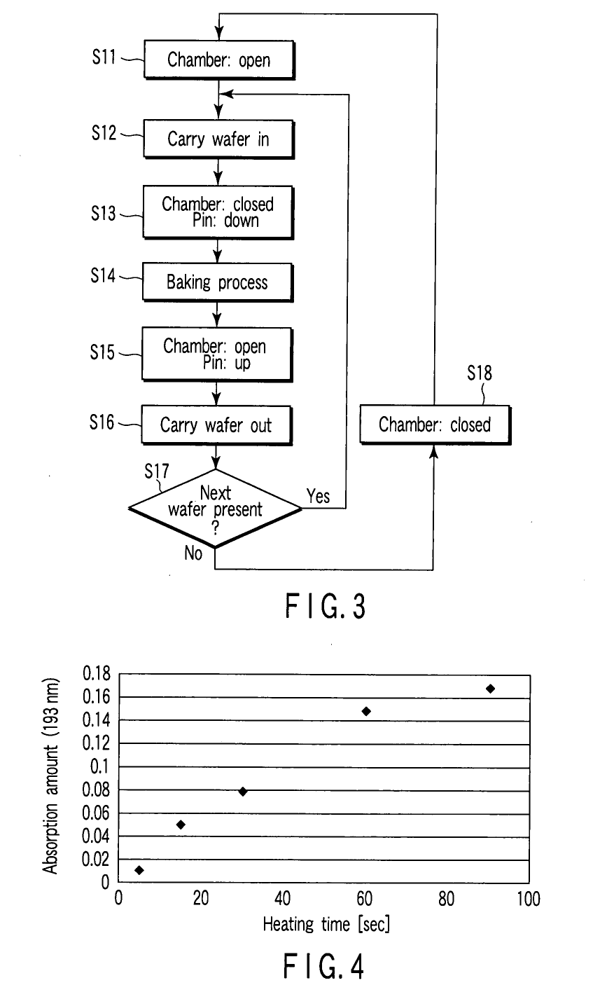

Prior to description of the substrate processing method of the embodiment of the present invention, a general baking process will be described below. FIG. 3 is a flowchart showing the procedures of a general baking process performed by using a heat treatment apparatus shown in FIG. 2.

A film, for example, an organic antireflection film, is formed on the wafer 15 by spin coating, and the wafer 15 is transferred to a position in the vicinity of the heat treatment apparatus by the transfer arm 18. Then, the lid 11 of the chamber 10 of the heat treatment apparatus is opened (step S11), and the wafer 15 is transferred into the chamber 10 (step S12). Subsequently, the support pins 17 supporting the wafer 15 are lowered, and the lid 11 of the chamber 10 is closed (step S13). Thereafter, a baking process of the wafer 15 is started in the chamber 10 (step S14).

During the baking process, air (or N₂) is supplied to the chamber from the air inlet 13 provided in the upper part of the chamber 10. The air supplied to the chamber is exhausted from the plural exhaust ports in the lower portion of the chamber 10 through the portion above the wafer 15. After the baking process is carried out for a predetermined time, the lid 11 of the chamber 10 is opened, and the support pins 17 are raised (step S15). Further, the wafer 15 is placed on the transfer arm 18 in order to be carried out of the chamber (step S16).

In the case where the next wafer has already arrived at the heat treatment apparatus (step S17), the wafer which has already been processed is carried out of the chamber and, at the same time, the next wafer is transferred into the chamber, and step 12 and subsequent steps are repeated. On the other hand, in the case where the next wafer has not yet arrived at the heat treatment apparatus in step S17, the arrival of the next wafer is waited for in the state where the chamber 10 is closed (step S18). Thereafter, when the next wafer arrives at the heat treatment apparatus, the wafer is processed according to step S11 and subsequent steps.

An example will be described below in which the organic antireflection film is processed under standard conditions of a baking temperature of 205° C. and baking time of 60 seconds according to the procedures of the baking process shown in FIG. 3. As a result of processing the organic antireflection film at a rate of a supply airflow into the chamber 10 of 2 L/min and at a rate of an exhaust airflow from the chamber of 2 L/min, more than one thousand particles having a size of 0.13 μm or more were detected on the organic antireflection film. Then, it was determined that sufficient exhausting capability cannot be achieved by the initial supply airflow rate and exhaust airflow rate, and the supply airflow rate was increased to 10 L/min and the exhaust airflow rate was also increased to 10 L/min in order to process the organic antireflection film. As a result, the number of particles having a size of 0.13 μm or more was reduced to ten or less. However, fifty particles having a size of 0.1 to 0.13 μm were detected. From these facts, it can be seen that particles are produced on the organic antireflection film even when a heat treatment apparatus having a sufficient exhausting capability is used.

The reason particles are produced even when a heat treatment apparatus having a sufficient exhausting capability is used will be described below. After coating the substrate to be processed with the organic antireflection film, a quartz glass plate was arranged above the organic antireflection film so as to face the film. In this state, the baking process was performed in order to cause the sublimate produced from the organic antireflection film to adhere to the quartz glass plate. The property of absorbing UV light possessed by the sublimate was utilized to measure an amount of UV light absorbed by the sublimate that adhered to the quartz glass plate by irradiating the quartz glass plate with UV light.

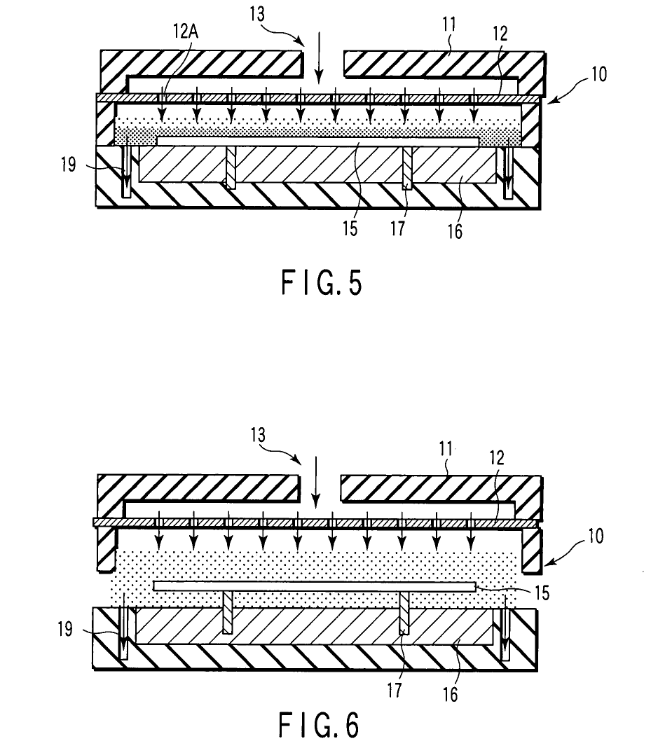

Results of measurement of the absorption amount of UV light performed at a baking temperature of 205° C. by using the time during which the quartz glass plate was caused to face the organic antireflection film (corresponding to the heating time) as a parameter, are shown in FIG. 4. From the fact that the absorption amount of UV light increased with heating time, even after about 60 seconds heating time, it is seen that the sublimate is produced from the organic antireflection film even after only 60 seconds have elapsed from the start of the measurement. From the above fact, it can be assumed that the state in the chamber 10 immediately before termination of the baking process is that as shown in FIG. 5 where the sublimate is floating therein, even when the exhaustion of air is sufficient. As a result, it can be assumed that when the chamber 10 was opened to exchange the wafer 15, the temperature of the atmosphere inside the chamber was quickly lowered so as to produce minute particles (as shown in FIG. 6), thereby causing the particles to adhere to the wafer 15.

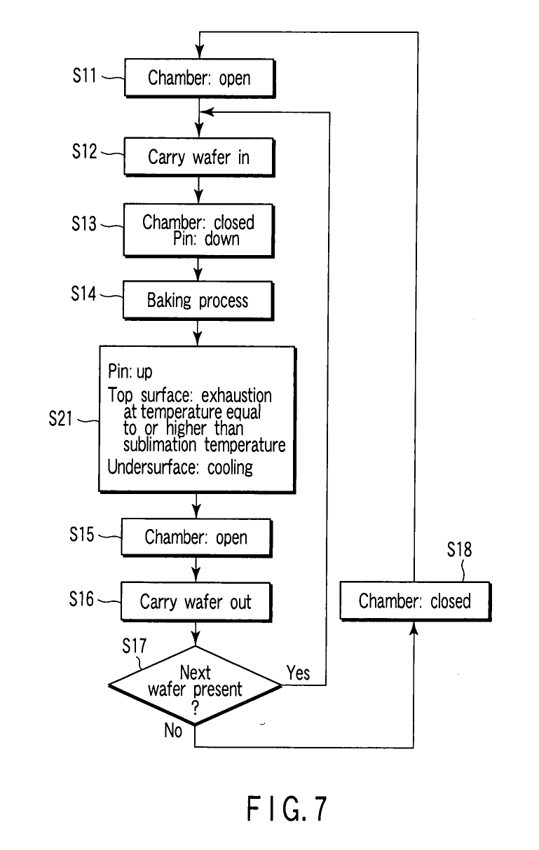

The substrate processing method of the embodiment of the present invention for preventing adhesion of the particles described above will be explained below. FIG. 7 is a flowchart showing the procedures of the baking process of the embodiment of the present invention to be performed by using the heat treatment apparatus shown in FIG. 2.

A film, for example, an organic antireflection film, is formed on the wafer 15 by spin coating, and the wafer 15 is transferred to a position in the vicinity of the heat treatment apparatus by the transfer arm 18. Then, the lid 11 of the chamber 10 of the heat treatment apparatus is opened (step S11), and the wafer 15 is transferred into the chamber 10 by the transfer arm 18 (step S12).

Subsequently, the transfer arm 18 is returned to the outside of the chamber, and the lid 11 of the chamber 10 is closed. Further, the support pins 17 supporting the wafer 15 are lowered, and the wafer 15 is placed on the heating plate 16 (step S13). Thereafter, a baking process of the wafer 15 is started in the chamber 10 by heating the heating plate 16 (step S14). During the baking process, air (or N₂) is supplied to the chamber from the air inlet 13 provided in the upper part of the chamber 10. The air supplied to the chamber is exhausted from the plural exhaust ports 19 in the lower portion of the chamber 10 through the portion above the wafer 15.

After the baking process is carried out for a predetermined time, the support pins are raised, the wafer 15 is separated from the heating plate 16, thereby to cool the wafer 15. The air entering the chamber from the air inlet 13 is heated by the top plate 12 to a temperature higher than the sublimation temperature of the sublimate, flows along the top surface of the wafer 15, and is discharged from the exhaust ports (step S21). Cooling of the wafer 15 may be performed by separating the wafer 15 from the heating plate 16 as described above, or by blowing a cooled gas against the backside (surface on which no film is formed) of the wafer 15. Further, cooling of the wafer 15 may be performed by bringing the backside of the wafer 15 into contact with a cooled plate. Still further, the above methods may be combined with each other. The air introduced into the chamber from the air inlet 13 is heated by the top plate 12 as described above. Alternatively, the air itself may be heated before it is introduced into the chamber 10.

After the air inside the chamber heated to the temperature higher than the sublimation temperature is exhausted until the sublimate inside the chamber 10 disappears, the lid of the chamber 10 is opened (step S15), and the wafer 15 is placed on the transfer arm 18 in order to be carried out of the chamber (step S16).

In the case where the next wafer has already arrived at the heat treatment apparatus (step S17), the processed wafer is carried out of the chamber and, at the same time, the next wafer is carried into the chamber 10 in order to repeat the processes of step S12 and subsequent steps. On the other hand, in the case where the next wafer has not yet arrived at the heat treatment apparatus, the arrival of the next wafer is waited for in a state where the chamber 10 is closed (step S18). Thereafter, when the next wafer arrives, the wafer is subjected to the processes of step S11 and subsequent steps.

In the embodiment of the present invention, in order to prevent particles (sublimate) from adhering to the wafer in the heat treatment process, after the baking process is terminated, production of the sublimate is stopped by cooling the wafer to a temperature lower than the sublimation temperature of the organic antireflection film while causing a gas to flow at a predetermined flow rate along the top surface of the wafer and exhausting the sublimate as shown in FIG. 7. The exhaustion is further continued, and when the sublimate inside the chamber has completely disappeared, the chamber is opened to exchange the wafer. At this time, a gas heated to a temperature higher than the sublimation temperature of the sublimate is caused to flow along the top surface of the wafer. By causing a gas heated to a temperature higher than the sublimation temperature to flow, the sublimate is prevented from solidifying and adhering to the wafer.

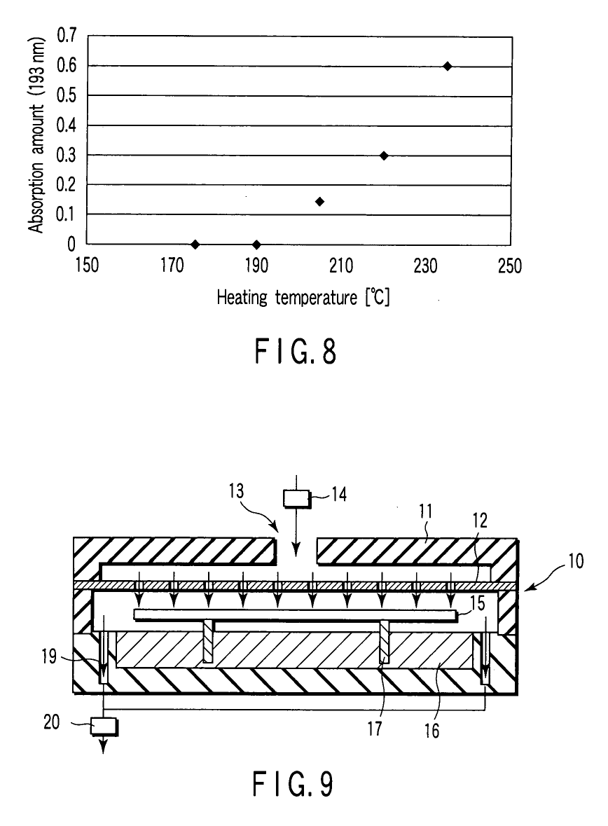

As for the sublimation temperature of the organic antireflection film, it was determined by arranging a quartz glass plate above the substrate to be processed so as to cause it to face the substrate to be processed, causing the sublimate to adhere to the quartz glass plate, and measuring the absorption amount of UV light. Changes in absorption amount of UV light obtained when the heating temperature of the substrate to be processed is changed are shown in FIG. 8. From the above results, it was found that no sublimate is produced by cooling the substrate to be processed to 190° C.

Thus, after the termination of the baking process of the organic antireflection film, exhaustion was performed in such a manner that the temperature of the substrate to be processed is lower than 190° C., and the temperature of the gas caused to flow along the top surface of the substrate to be processed is not lower than 190° C. More specifically, as shown in FIG. 9, exhaustion of the chamber was performed for ten seconds in a state where the support pins 17 were raised in order to separate the substrate 15 to be processed from the heating plate 16, and the temperature of the top plate 12 was kept at 200° C. By performing such processing, the number of particles on the substrate to be processed was largely reduced to five particles or less.

In the embodiment described above, the gas to be supplied onto the wafer is heated to a temperature higher than the sublimation temperature by heating the top plate. However, the gas itself to be introduced into the chamber by the air supply means may be heated. Further, in the case where the sublimation temperature and the solidification temperature are different from each other, the temperature of the gas to be supplied onto the wafer may be equal to or higher than the solidification temperature. Furthermore, if it is possible to perform exhaustion in such a manner that even when the sublimate solidifies, the sublimate does not adhere to the substrate to be processed, the temperature of the gas may become equal to or lower than the sublimation temperature or the solidification temperature. Furthermore, cooling of the substrate to be processed is performed by lifting up the support pins in order to separate the substrate to be processed from the heating plate. However, cooling of the substrate to be processed may be performed by lifting up the support pins and blowing a cooled gas against the backside of the substrate to be processed or by bringing the backside of the substrate to be processed into contact with a cooled plate.

According to the embodiment of the present invention, it is possible to reduce the number of particles that adhere to the surface of the substrate to be processed, and improve a yield in the manufacture of a semiconductor device.

Incidentally, the embodiment described above is not limited to the only one embodiment, but can be formed into various embodiments by changing the structure or adding various structures thereto. Furthermore, the embodiment described above can be implemented by appropriately modifying it within a scope in which the gist thereof is not changed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A substrate processing method of heating a substrate to be processed coated with a film containing a solvent in a single wafer processing manner, comprising:
heating the substrate to be processed for a predetermined time by arranging the substrate to be processed in the proximity of a heated heating plate while passing a gas along a top surface of the substrate to be processed at a predetermined flow rate; and
cooling the substrate to be processed to a temperature lower than a sublimation temperature of a substance contained in the film containing the solvent while passing a gas heated to a temperature equal to or higher than the sublimation temperature of the substance contained in the film containing the solvent along the top surface of the substrate to be processed.

2. The substrate processing method according to claim 1, wherein the film containing the solvent includes an antireflection film.

3. The substrate processing method according to claim 2, wherein the antireflection film is an organic film.

4. The substrate processing method according to claim 1, wherein when the substrate to be processed is heated, the substrate to be processed is placed on the heating plate.

5. The substrate processing method according to claim 1, wherein when the substrate to be processed is cooled, the substrate to be processed is separated from the heating plate.

6. The substrate processing method according to claim 1, wherein when the substrate to be processed is cooled, a cooled gas is blown against a backside of the substrate to be processed.

7. The substrate processing method according to claim 1, wherein when the substrate to be processed is cooled, a cooled plate is brought into contact with the substrate to be processed.

8. A substrate processing method of heating a substrate to be processed coated with a film containing a solvent in a single wafer processing manner, comprising:
heating the substrate to be processed for a predetermined time by arranging the substrate to be processed in the proximity of a heated heating plate while passing a gas along a top surface of the substrate to be processed at a predetermined flow rate; and
cooling the substrate to be processed to a temperature lower than a solidification temperature of a substance contained in the film containing the solvent while passing a gas heated to a temperature equal to or higher than the solidification temperature of the substance contained in the film containing the solvent along the top surface of the substrate to be processed.

9. The substrate processing method according to claim 8, wherein the film containing the solvent includes an antireflection film.

10. The substrate processing method according to claim 9, wherein the antireflection film is an organic film.

11. The substrate processing method according to claim 8, wherein when the substrate to be processed is heated, the substrate to be processed is placed on the heating plate.

12. The substrate processing method according to claim 8, wherein when the substrate to be processed is cooled, the substrate to be processed is separated from the heating plate.

13. The substrate processing method according to claim 8, wherein when the substrate to be processed is cooled, a cooled gas is blown against a backside of the substrate to be processed.

14. The substrate processing method according to claim 8, wherein when the substrate to be processed is cooled, a cooled plate is brought into contact with the substrate to be processed.

15. A semiconductor device manufacturing method, comprising:
coating a semiconductor substrate with a film containing a solvent;
baking the semiconductor substrate coated with the film containing the solvent, the baking the semiconductor substrate including
heating the semiconductor substrate for a predetermined time by arranging the semiconductor substrate in the proximity of a heated heating plate while passing a gas along a top surface of the semiconductor substrate at a predetermined flow rate; and
cooling the semiconductor substrate to a temperature lower than a sublimation temperature of a substance contained in the film containing the solvent while passing a gas heated to a temperature equal to or higher than the sublimation temperature of the substance contained in the film containing the solvent along the top surface of the semiconductor substrate,
forming a resist film on the baked semiconductor substrate;
baking the semiconductor substrate on which the resist film is formed;
subjecting the baked resist film to pattern exposure;
baking the resist film subjected to pattern exposure; and
developing the exposed and baked resist film.

16. The semiconductor device manufacturing method according to claim 15, wherein the film containing the solvent includes an antireflection film.

17. The semiconductor device manufacturing method according to claim 15, wherein when heated, the semiconductor substrate is placed on the heating plate.

18. The semiconductor device manufacturing method according to claim 15, wherein when cooled, the semiconductor substrate is separated from the heating plate.

19. The semiconductor device manufacturing method according to claim 15, wherein when the semiconductor substrate is cooled, a cooled gas is blown against a backside of the semiconductor substrate.

20. The semiconductor device manufacturing method according to claim 15, wherein when the semiconductor substrate is cooled, a cooled plate is brought into contact with the semiconductor substrate.
